(19) United States
(12) Patent Application Publication
(10) Pub. No.: US 2026/0126485 A1
(43) Pub. Date: May 7, 2026

(54) AUTOMATIC CONFIGURATION OF TEST SYSTEM COMPONENTS

(71) Applicant: Toyota Jidosha Kabushiki Kaisha, Toyota-shi Aichi-ken (JP)

(72) Inventors: Sean S. Norris, Washington, DC (US); Joshua S Smith, Livonia, MI (US); Vijay Kumar Adusumilli, McKinney, TX (US)

(73) Assignee: Toyota Jidosha Kabushiki Kaisha, Toyota-shi Aichi-ken (JP)

(21) Appl. No.: 19/426,805

(22) Filed: Dec. 19, 2025

Related U.S. Application Data
(63) Continuation-in-part of application No. 18/771,089, filed on Jul. 12, 2024.

(51) Int. Cl. G01R 31/317; G01R 31/319

(52) U.S. Cl. CPC G01R 31/31713; G01R 31/31912

(57) ABSTRACT

Systems, methods, and other embodiments described herein relate to improving the testing of electronic devices. In one embodiment, a method includes identifying an interface device and a test device to be connected during a test. The method also includes loading, based on the interface device and the test device, a hardware template for the test from memory. The hardware template indicates a test device definition that includes configuration information for a port of the test device. The method also includes providing the configuration information to facilitate mediating communication with the test device.

### CROSS-REFERENCE TO RELATED APPLICATIONS

This application is a continuation-in-part of U.S. Non-Provisional Application No. 18/771,089, filed on July 12, 2024, which is herein incorporated by reference in its entirety.

### TECHNICAL FIELD

The subject matter described herein relates, in general, to testing electronic devices and, more particularly, to the templatized configuration of test system components.

### BACKGROUND

Developers implement test benches to provide a controlled environment for developing software for new devices and testing that the new devices function as expected. In general, test benches are built on a per-device basis. As one example, in the context of vehicle electronic control units (ECUs), a test bench may include a custom wire harness that connects various different devices together while also providing additional connections for testing purposes. However, the uniqueness of these test benches requires institutional knowledge to effectively use them, thus limiting the ability for these benches to be shared between many developers and complicating access overall. Moreover, as the complexity of the device or arrangement of devices under test increases and/or testing requirements increase, the wiring harnesses also become more complex and difficult to build and maintain. Additionally, the increase in complexity also leads to increased costs for a test setup that is not reusable, thereby leading to further waste.

### SUMMARY

In one embodiment, example systems and methods relate to a manner of enhancing the reliability and efficiency of testing electronic devices. In one embodiment, a test template system that automatically configures hardware components of a test system is disclosed. The test template system includes a processor and a memory storing machine-readable instructions that, when executed by the processor, cause the processor to identify an interface device and a test device to be connected during a test. The memory further stores machine-readable instructions that, when executed by the processor, cause the processor to load, based on the interface device and the test device, a hardware template for the test. The test template is loaded from memory. The hardware template indicates a test device definition that includes configuration information for a port of the test device. The memory further stores machine-readable instructions that, when executed by the processor, cause the processor to provide the configuration information to facilitate mediating communication with the test device.

In one embodiment, a non-transitory machine-readable medium for enhancing the reliability and efficiency of testing electronic devices and including instructions that, when executed by a processor, causes the processor to perform one or more functions is disclosed. The instructions include instructions to identify an interface device and a test device to be connected during a test. The instructions further include instructions that, when executed by the processor, cause the processor to load, based on the interface device and the test device, a hardware template for the test. The test template is loaded from memory. The hardware template indicates a test device definition that includes configuration information for a port of the test device. The instructions also include instructions to provide the configuration information to facilitate mediating communication with the test device.

In one embodiment, a method for enhancing the reliability and efficiency of testing electronic devices is disclosed. In one embodiment, the method includes identifying an interface device and a test device to be connected during a test. The method also includes loading, based on the interface device and the test device, a hardware template for the test. The test template is loaded from memory. The hardware template indicates a test device definition that includes configuration information for a port of the test device. The method also includes providing the configuration information to facilitate mediating communication with the test device.

### BRIEF DESCRIPTION OF THE DRAWINGS

The accompanying drawings, which are incorporated in and constitute a part of the specification, illustrate various systems, methods, and other embodiments of the disclosure. It will be appreciated that the illustrated element boundaries (e.g., boxes, groups of boxes, or other shapes) in the figures represent one embodiment of the boundaries. In some embodiments, one element may be designed as multiple elements or multiple elements may be designed as one element. In some embodiments, an element shown as an internal component of another element may be implemented as an external component and vice versa. Furthermore, elements may not be drawn to scale.

FIG. 1 illustrates one embodiment of an interface system that is associated with an adaptable platform for testing electronic devices.

FIG. 2A illustrates one embodiment of an interface device and connected devices.

FIG. 2B illustrates one embodiment of the interface device of FIG. 2A with additional details illustrated.

FIG. 3 illustrates a flowchart of communications between an interface device and a test service.

FIG. 4 is a flowchart representing a method associated with using an interface device to mediate communications with a device under test.

FIG. 5 illustrates one configuration of an edge service that includes multiple interface devices.

FIG. 6 illustrates one configuration of a cloud-based service that utilizes interface devices to provide emulation of physical wire harnesses.

FIG. 7 is a flowchart illustrating a method associated with emulating a wire harness.

FIG. 8 is a diagram illustrating one arrangement of a rack system that houses multiple networks of interface devices.

FIG. 9 illustrates one embodiment of a test template system that is associated with setting up a templatized test system.

FIG. 10 illustrates a flowchart for one embodiment of a method that is associated with setting up a templatized test system.

FIG. 11 illustrates a test device definition file, according to an example described herein.

FIG. 12 illustrates an interface device definition file, according to an example described herein.

FIG. 13 illustrates one example of a port-to-port mapping, according to an example described herein.

FIG. 14 illustrates one example of a wiring diagram between a test device connector and an interface device connector, according to an example described herein.

FIG. 15 illustrates a flowchart for one embodiment of a method that is associated with setting up a templatized test system.

### DETAILED DESCRIPTION

Systems, methods, and other embodiments associated with testing electronic devices using an adaptable interface are disclosed. As previously noted, test benches can be complex to implement because of various considerations, including the complexity of the device(s) being tested. This leads to increased costs and waste since these test benches are complex to implement and are unique to the particular instance, thereby not being reusable. By way of example, within the context of a vehicle, a wiring harness may connect with a dozen or more electronic control units. Each of the electronic control units (ECUs) undergoes development and testing to implement particular functionality in the vehicle in a manner that the developers desire. Thus, each different configuration of systems within a vehicle during development and each separate iteration of different ECUs that may be selected requires a new wiring harness to be manually fabricated. Consequently, the ability to iterate on designs when developing a new platform can be costly, thereby potentially limiting development.

Therefore, in at least one approach, an inventive system is disclosed that provides an adaptable interface and associated logic to improve the testing of electronic devices. For example, in at least one aspect, an interface device is comprised of a controller, a memory, a bridge, and a connector for supporting communication with a device under test (i.e., an electronic device, which is also referred to as a test device herein). The electronic device may take many different forms, including a module with multiple die packages, a single die package, a system on a chip (SoC), and so on. As described herein, the electronic device that is tested is generally an electronic control unit (ECU) as may be used within a vehicle. It should be appreciated that while the present disclosure focuses on the context of a vehicle, the disclosed devices, systems, and methods are applicable to other contexts and the discussed context should not be construed as limiting.

In any case, consider that an electronic device, such as an ECU or multiple ECUs are generally connected using a complex wiring harness when installed within a vehicle. The wiring harness may include a connector for each separate ECU with wiring therebetween. Moreover, within the context of testing, the wire harness may be further implemented to include diagnostic connectors for providing diagnostic signals. However, as noted previously, specifically designing a unique wiring harness for each different configuration of electronic devices that may need to be tested is complex. As such, the interface device resolves this issue by using the bridge to connect with multiple electronic devices under test, such as multiple different ECUs. The bridge connects to a respective electronic device via connector pins. The connector pins connect the bridge with an explicit connector port associated with the electronic device being tested (e.g., an ECU) or directly to pins of a die package or other electronic device (e.g., sensor).

Consequently, the connector pins may be specific to the particular electronic device, but this is in place of a more complex harness that cannot be modified for different arrangements. Because the connector pins from the bridge to the electronic device are unique in each instance, the interface device further includes a memory, which may be an EEPROM or similar type of non-volatile memory, that stores configuration information about the electronic device and other devices under test that are connected via other connector pins to the bridge. The contents of the configuration information may vary by implementation but generally include descriptive data identifying the electronic device (e.g., serial number or other identifier, version number, etc.) and a mapping of the connector pins. The mapping identifies the correlation of the pins of the electronic device with the ports of the bridge on which the pins are connected and exposed for communication. Accordingly, a controller mediates access to the electronic device by communicating the configuration information so that a test server or other test administering device can access the electronic device via the bridge by using the mapping.

In various further arrangements, the interface device communicates with an edge service and/or a cloud service. The edge service may function over a network connection with the interface device to aggregate configuration information from multiple different interface devices that connect with different electronic devices. Thus, the edge service may connect with the interface device via an Ethernet switch or communication network and functions to acquire the configuration information for a set of electronic devices associated with different interface devices. As a result, the edge service generates a mapping of the set of electronic devices and the associated connections provided via the respective bridges. A testing system can then use the edge service to form a virtual wire harness through the use of the mapping to emulate connections between the different electronic devices. That is, the edge service can provide for connecting the different electronic devices via the interface devices in a similar manner as would occur with a physical wire harness, but without the complexity and waste of implementing the wire harness.

Moreover, a cloud service may further aggregate mappings from multiple edge services to provide additional functionality. The cloud service can provide access for remote clients in addition to permitting additional functionality, such as the provisioning of more complex virtual harnesses between separate edge services, reservations for scheduling testing among different entities, data analytics, and so on. In this way, the disclosed approach is able to improve testing of electronic devices by avoiding complex, expensive, and potentially wasteful physical harnesses for testing.

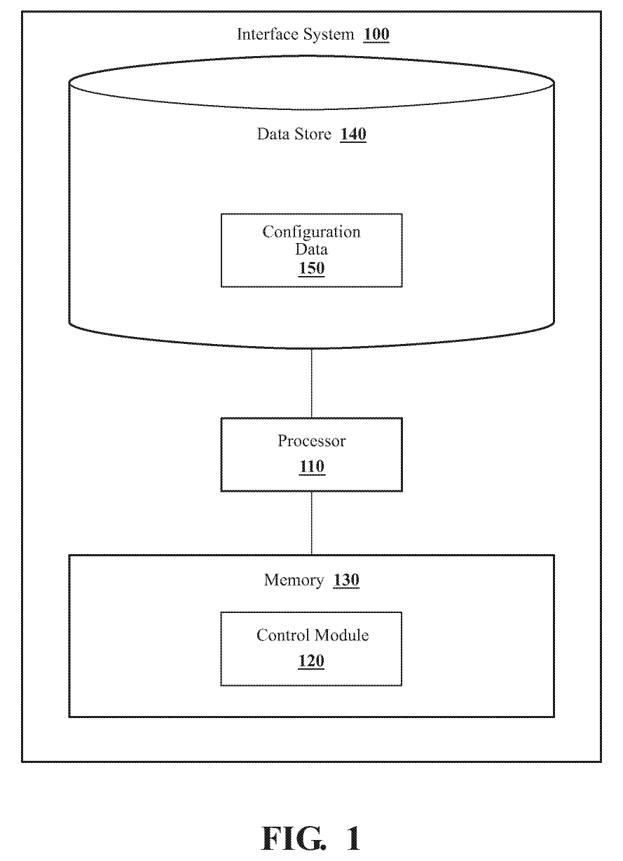

With reference to FIG. 1, one embodiment of an interface system 100 is illustrated. The interface system 100 is shown as including a processor 110, which may be integrated within the interface system 100 or may be associated with a separate computing device, such as a server, cloud-computing system, and so on. Accordingly, the processor 110 may be a part of the interface system 100, or the interface system 100 may access the processor 110 through a data bus or another communication path. In one embodiment, the interface system 100 includes a memory 130 that stores a control module 120. The memory 130 is a random-access memory (RAM), read-only memory (ROM), a hard-disk drive, a flash memory, or another suitable memory for storing the module 120. The module 120 is, for example, computer-readable instructions that, when executed by the processor 110, cause the processor 110 to perform the various functions disclosed herein. In alternative arrangements, the module 120 is independent from the memory 130 and is, for example, comprised of hardware elements (e.g., arrangements of logic gates). Thus, the module 120 is alternatively an ASIC, a hardware-based controller, a composition of logic gates, or another hardware-based solution.

The interface system 100, as illustrated in FIG. 1, is an abstracted form of the interface system 100 as may be implemented as part of an interface device, an edge service, and/or a cloud-computing system. It should be appreciated that the functionality discussed in relation to the interface system 100 may be wholly retained within a single device, such as the interface device itself, or may be distributed among multiple different devices, such as interface devices, computing elements functioning as edge services, computing elements functioning as cloud services, and so on. As such, the particular arrangement described in relation to FIG. 1 is not intended to be limiting but as an example of how the specific functions described herein may be executed in relation to a computing device.

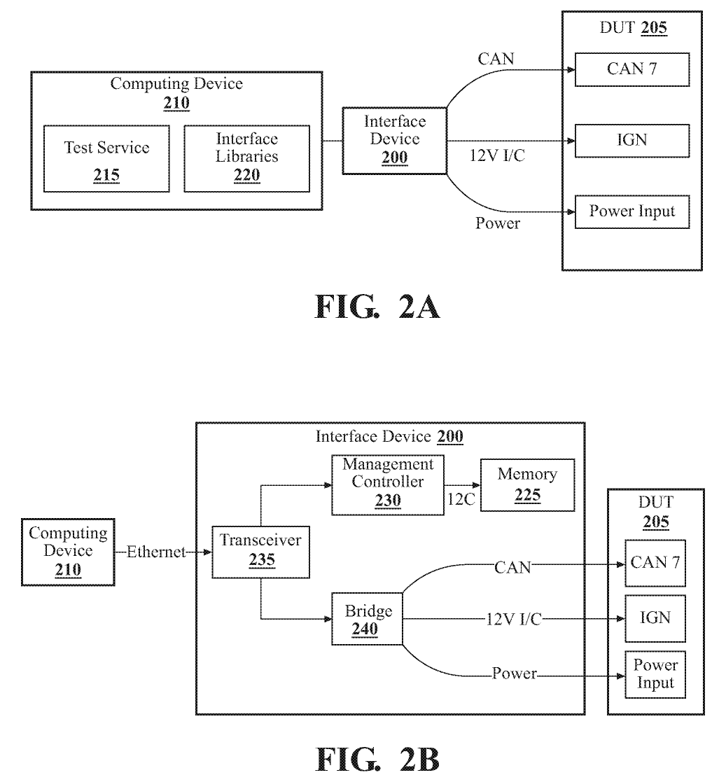

With reference to FIG. 2A, one example of an interface device 200 (also referred to as a hardware interface (HWI) herein) is illustrated. The interface device 200, as shown, connects with a device under test (DUT) 205. The DUT 205 may, in general, be any electronic device that is being tested, such as an ECU, or other electronic module. The interface device 200 connects with the DUT 205 via connector pins that are specific to the DUT 205. As illustrated in the present example, the connector pins include three primary connections that may be comprised of multiple separate wires each. In particular, the DUT 205 is connected via a control area connection (CAN), a 12 V I/O, and a power line. These separate portions of the connector pins interface with a CAN port, an IGN port, and a power input, respectively. Thus, as can be appreciated from the present example, the connector pins for each separate DUT may be unique to that DUT and are, therefore, implemented, in at least one arrangement, on a per-device basis. As an additional aspect, while the interface device 200 is shown in FIG. 2A as connecting with a single DUT 205, in various arrangements, the interface device 200 is capable of connecting multiple separate DUTs. The number of devices to which the interface device 200 connects is generally only limited by attributes of hardware included within the interface device 200 itself, such as a communication bridge that may have a certain number of ports within which to connect.

Separately, the interface device 200, in the illustrated example, connects with a computing device 210. The computing device 210 is, in one or more configurations, a server, a desktop computer, a laptop, or another device that is capable of executing instructions for testing the DUT 205 and communicating via the interface device 200. The computing device 210 executes a test service 215 that includes instructions for testing the DUT 205. For example, the test service 215 may include instructions to provide automated testing and/or a manual interface to the DUT for manual testing. The testing may take different forms depending on the particular use, but can include diagnostics testing, development of software for use on the DUT 205, debugging, and so on.

In any case, the test service 215 uses interface libraries 220 to provide for interfacing with the interface device 200 and the DUT 205. That is, the interface libraries 220 may form an application programming interface (API) or other software library that provides functions for facilitating communications between the computing device 210 and the interface device 200 over an Ethernet connection or other electronic communication link. For further details of the interface device 200, consider FIG. 2B, which shows additional components of one example of the interface device 200 of FIG. 2A. As illustrated, the interface device 200 includes a memory 225, a management controller 230, a transceiver 235, and a bridge 240.

The transceiver 235 provides for communicating over an Ethernet connection or other communication link with the computing device 210 and may further route communications within the interface device 200 itself. For example, depending on the request provided by the computing device 210 via the interface libraries 220, the transceiver 235 may route the communication to the management controller 230 or directly to the bridge 240. The management controller 230 may be an ASIC, logic, or other programmable processing device that handles initialization requests from the computing device 210 or another external device. For example, the management controller 230 may receive an initialization request for information about one or more DUTs connected to the interface device 200. In general, the interface device 200 stores configuration information for each DUT that is connected with the interface device 200. The interface device 200 may store the configuration information in the memory 225. The memory 225 is, for example, an EEPROM, or other non-volatile memory.

The configuration information stored in the memory 225 includes information about the DUT 205 and the connector pins that connect the DUT 205 with the bridge 240. The information about the DUT 205 can include a device identifier, version number, and other attributes (e.g., device specifications, such as memory, processing capabilities, etc.). The connector pins information includes a mapping or listing of how the pins of the DUT 205 are connected with the bridge 240. Thus, the pin information correlates the pins to ports of the bridge 240 so that the requesting device (i.e., the computing device 210) can generate a mapping for subsequently powering, controlling, and otherwise communicating with the DUT 205. Accordingly, the test service 215 uses the interface device 200 to build a mapping that provides for routing signals generated by the test service 215 when executing a test program to the appropriate pins of the DUT 205. In general, the mapping defines ports associated with the bridge 240 for communicating signals on particular pins of the DUT 205. In this way, the interface device 200 exposes the DUT 205 for interactions with external devices.

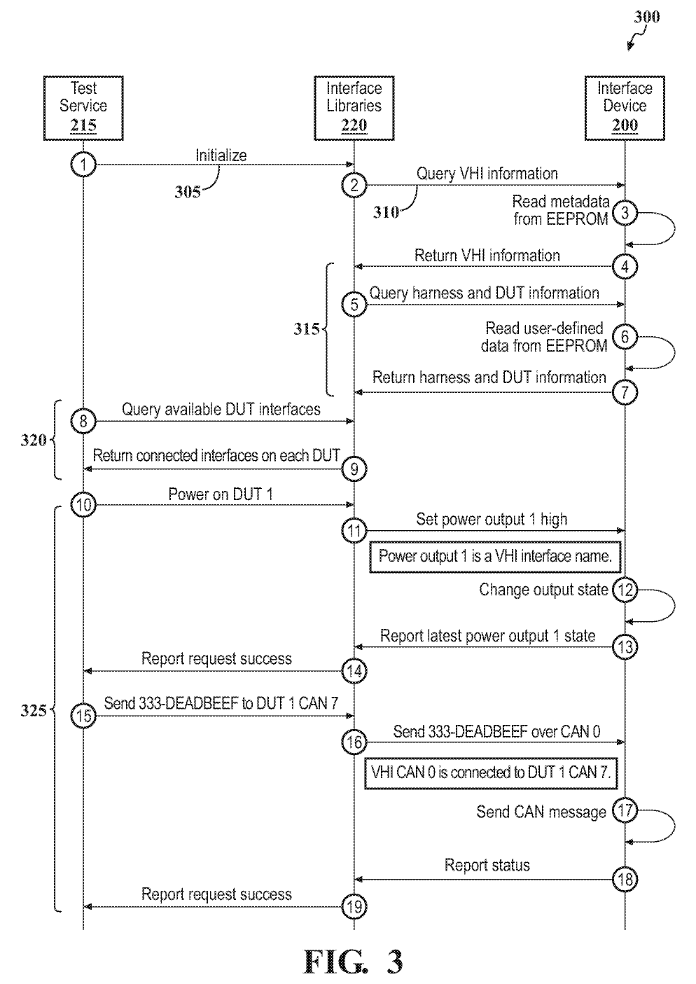

Continuing to FIG. 3, an example 300 of communications between the test service 215, the interface library 220, and the interface device 200 are represented. As additional context, the test service 215 is, in at least one arrangement, an automated testing program that provides a defined set of inputs to the DUT 205 while recording responses in order to characterize the performance of the DUT 205 (e.g., whether the DUT 205 is operating as expected). In further arrangements, the test service 215 may be a development environment for generating software code and loading the software code into the DUT 205 for execution. In still further arrangements, the test service 215 is a manual testing interface that allows a user to select inputs to provide directly to the DUT 205. In yet further arrangements, the test service 215 is a client for interfacing with external requests from remote applications. For example, the test service 215 may interface with an edge service, a cloud-based service, or another entity in order to provide access to the DUT 205 or other attached DUTs of the interface device 200.

In any case, the test service 215 initiates communication with the interface device 200 at 305. In order to provide the communication in the appropriate form, the interface libraries 220, which may be implemented as instructions executing as part of the test service 215, process the request into a query to the interface device, as shown at 310. Responsive to the query, the interface device 200 via the management controller 230 acts to retrieve the configuration information from the memory 225 and communicate the configuration information back to the interface libraries, which is shown as a multistep process at 315. While shown as being retrieved over multiple steps, in various arrangements, the interface device 200 may provide contents of the configuration information in a single communication or in multiple communications depending on, for example, buffer sizes and/or other hardware constraints.

The interface libraries 220 then function to generate the mapping of the pins of the DUT 205 connected with the interface device 200 so that the interface library 220 can translate requests from the test service 215 and communicate the requests on the appropriate ports of the bridge 240. In any case, once the interface libraries 220 function to initialize the mapping, which may be implemented as list, a table, or another data structure that correlates the ports with the pins, the test service 215 is able to query the interface libraries 220 for information about the DUT 205, as shown at 320, such as an identifier, version number, connected pins/interfaces available with the DUT 205, and so on. It should be appreciated that while a single DUT 205 is described, in further arrangements, the information returned from the interface device 200 may include multiple DUTs. Thus, the interface libraries 220 may then function to provide information about multiple separate DUTs. FIG. 3 further illustrates how the test service 215 proceeds to interact with the DUT 205 via the interface device 200. The illustrated communications generally involve powering the DUT 205, communicating with the DUT 205, and acquiring diagnostic information, such as status reports from the DUT 205 via the connected pins.

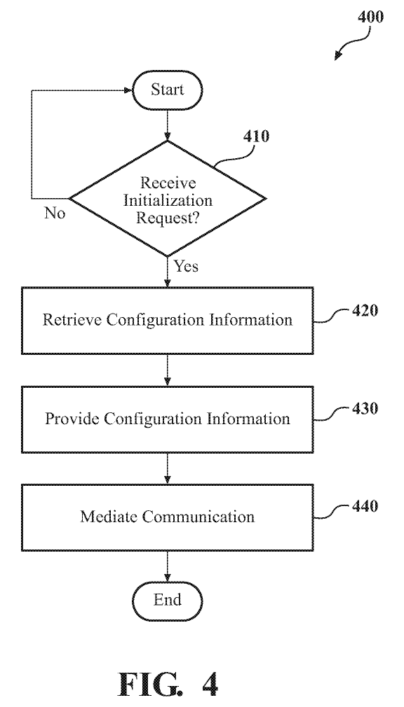

Additional aspects of using an interface device to facilitate communications for testing will be discussed in relation to FIG. 4. FIG. 4 illustrates a flowchart of a method 400 that is associated with adaptably interfacing with a device under test (DUT). Method 400 will be discussed from the perspective of the interface system 100 of FIG. 1 with further reference to the interface device 200 of FIGS. 2A-B. While method 400 is discussed in combination with the noted elements, it should be appreciated that the method 400 is not limited to being implemented within the interface system 100 but is instead one example of a system that may implement the method 400.

At 410, the control module 120 monitors for requests from a device connected to the interface device 200. For example, the interface device 200 may connect directly with another device or may connect with a network on which multiple different devices may communicate. In various arrangements, the interface device 200 connects with the network or directly to the other device via an Ethernet cable or other suitable communication link. In any case, the control module 120, which may be implemented, at least in part, as the management controller 230 monitors for communications and identifies or otherwise distinguishes between different communications. In one approach, the control module 120 monitors for a particular flag in the communication or otherwise parses the communication to determine if the communication is an initialization request to access a test device (i.e., DUT) that is connected with the bridge 240. If the communication is an initialization request, then the control module 120 proceeds to retrieve configuration information, as discussed at 420. Otherwise, the control module 120 continues to monitor the communications.

At 420, the control module 120 retrieves configuration information from a memory within the interface device 200. As previously described, the memory 225 stores configuration information for devices connected to the bridge 240 of the interface device 200. Thus, the memory 225 may store a different selection of configuration information depending on how many devices are connected to the interface device. As such, the control module 120, depending on the implementation, may retrieve the configuration information for all of the attached devices or for device(s) specified in the request. Thus, the control module 120 may parse the request to identify attributes of the request, which generally include the DUTs for which information is being requested. Of course, in alternative arrangements, the control module 120 may simply retrieve information for all DUTs for which configuration information is present in the memory 225.

At 430, the control module 120 provides the configuration information in response to the request. That is, the control module 120 (i.e., the management controller 230) communicates the retrieved configuration information to the requesting device via the transceiver 235. As outlined previously, the configuration information includes at least information that permits the requesting device (e.g., a client instance of the control module 120 executing on the computing device 210) to generate a mapping of pins of the test device for communicating with the test device over the network connection. The mapping then functions to facilitate communication with the test device.

At 440, the control module 120 mediates access to the test device(s). That is, for example, the control module 120 via the management controller 230 and the interface libraries 220 functions to control how the communications are routed to the test device(s). In various arrangements, the control module 120 simply leverages the generated mapping to provide communications to a particular DUT. However, in further arrangements, the control module 120 functions to emulate a wire harness. That is, when multiple separate DUTs are connected with the interface device 200 or with multiple interface devices as discussed further subsequently, the control module 120 can emulate a wire harness by directing the communications as though the test devices are wired in the same manner as if a physical wire harness between the test devices was present.

For example, signals generated by one test device (i.e., DUT 205) can be routed to another test device as though the devices are connected via a physical wire harness. However, the control module 120 instead functions to receive and relay the communications. This permits the control module 120 to emulate any configuration of test devices while further collecting diagnostic/analytics data about how the test devices are functioning. Moreover, the control module 120 can further extend an emulated wire harness among multiple interface devices in order to permit more complex arrangements.

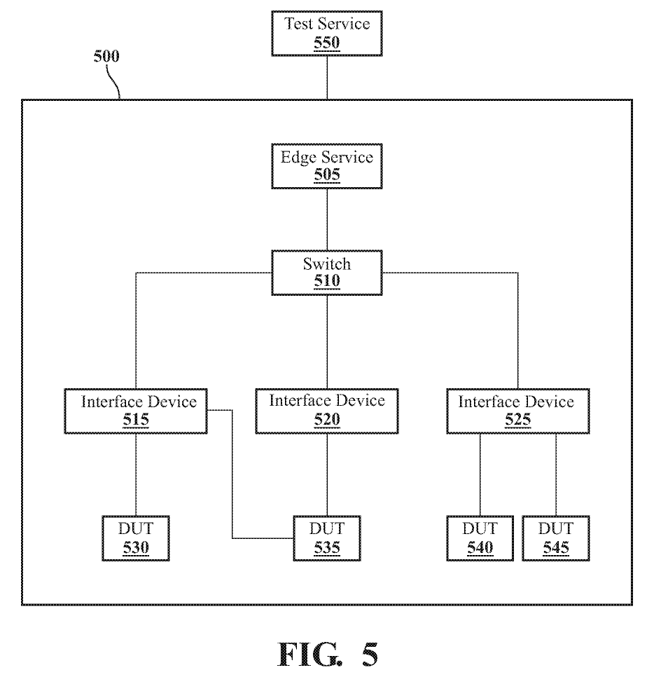

In that regard, consider FIG. 5, which illustrates an edge network 500. The edge network 500 is comprised of an edge service 505, which is generally similar to the computing device 210 of FIG. 2, a switch 510, and multiple interface devices 515, 520, and 525. The interface devices are configured in a similar manner as the interface device 200 of FIG. 2. However, as shown in the edge network 500, the arrangement of DUTs 530, 535, 540, and 545 is distinct from the previous example. In particular, the interface devices 515 and 520 are shown as sharing connections with the DUT 535. This example illustrates how the interface devices 515 and 520 are adaptable to different arrangements. In particular, the interface device 515 may provide for connecting with a portion of the pins of the DUT 535 while the interface device 520 may connect with different pins of the DUT 535. This circumstance may arise in different configurations due to, for example, the DUT 535 including more pins than what can be accommodated by a single interface, to split bandwidth between the separate interface devices 520, as a logical division of functions of the DUT 535 for improved management by the interface devices, and so on.

As one example, the DUT 535 may be a complex module that includes connections with multiple sensors, such as multiple cameras. Moreover, the DUT 535 may further include processing capabilities, management, and other functionality built into multiple different electronic components included therein. As such, the pins associated with the separate functions or in any combination that is desired can be divided between the two interface devices 515 and 520. In this arrangement, the interface devices 515 and 520 separately include configuration information for the pins connected to each individual device and also, in at least one arrangement, general identifying information (e.g., serial number, version number, etc.) for the DUT 535. In this arrangement, the interface device 515 still services the DUT 530 in the same manner as previously described. Accordingly, the ability to split the pins between separate interface devices provides additional flexibility in emulating a wire harness.

The edge network 500 provides for the edge service 505 managing the interface devices 515, 520, and 525. That is, the edge service 505 may function to aggregate information from the interface devices 515-525 in order to simplify access on the part of a test service 550. The test service 550 may be a remote client instance that communicates with the edge service 505 in order to perform automated tests and/or other functions on the DUTs 530-545 either individually or in a particular arrangement (e.g., via an emulated wire harness). Thus, the edge service 505 can be configured to perform various management functions, including implementing the interface libraries 220. In this way, the edge network 500 provides for implementing more complex arrangements of DUTs and also provides access to a wider variety of devices. Moreover, devices within an individual edge network are generally co-located, while separate edge networks may be physically distant and located remotely. In various arrangements, a cloud service, which is described in greater detail subsequently, may schedule jobs (i.e., access to particular DUTs to perform testing) within a single edge network, as opposed to spanning multiple edge networks, when feasible. This may provide for executing multiple copies of a test on separate edge networks in parallel. Of course, in further arrangements, virtual wire harnesses can be implemented, and tests performed in configurations that span multiple edge networks.

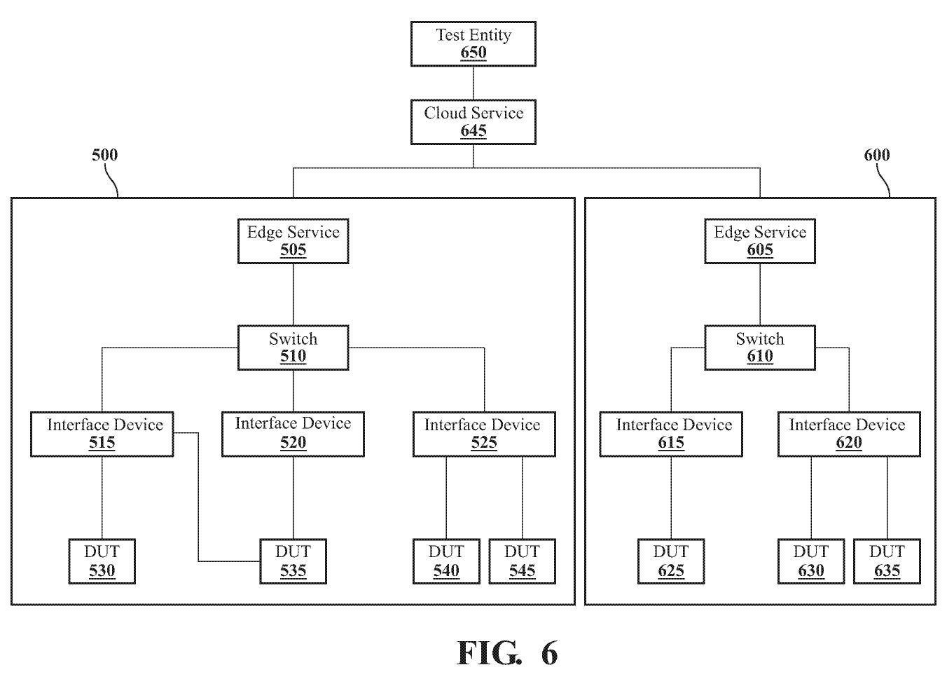

Continuing further with additional implementations of edge services, consider FIG. 6. FIG. 6 illustrates an example implementation of a cloud-based arrangement. As shown in FIG. 6, the edge network 500 functions in parallel with an additional edge network 600. In general, the overall configuration of the edge networks 500 and 600 is similar, except that the number of interface devices and the attached DUTs may vary depending on the particular implementation. For example, the edge network 600 is shown with an edge service 605 and a switch 610, which is similar to the edge network 500. However, the edge network 600 includes two interface devices 615 and 620 with associated DUTs 625, 630, and 640. In further examples, the number of interface devices per edge network may vary to include more or fewer as well as including more or fewer DUTs.

Additionally, a cloud service 645 is shown connected with the edge networks 500/600. The cloud service 645 may provide connections with more or fewer edge networks than shown in the present example. It should be appreciated that the present example is shown for illustrative purposes and should not be construed as limiting the overall structure. In any case, the cloud service 645 further functions to aggregate information about the DUTs within the connected interface devices of the networks 500/600. The cloud service 645 may be a service executing within a cloud-based device (e.g., a computing server) that is connected with a wide area network, the Internet, or another network for providing communications between remote devices. As such, the cloud service 645 functions to provide access to the DUTs via the connected networks and may further provide additional functions. For example, the cloud service 645 may provide reservations for accessing the DUTs, automatic interface, DUT, and emulated harness registration for access by remote clients, statistics/analytics reporting, native interface bridging, and so on.

In further arrangements, the cloud service 645 provides for bridging together the interfaces from the separate networks to emulate a wire harness. Stated otherwise, the cloud service 645 aggregates the information from the separate interface devices dispersed across the separate edge networks (e.g., 500 and 600) and can form a virtual wire harness between selected ones of the available DUTs. The cloud service 645 provides access for a test entity 650 that may include automated tests, developers, and/or other networked entities. In general, the cloud service 645 provides additional layers of functionality on top of the interface devices and the edge services, as previously described.

As one example, the cloud service 645 can provide access for the test entity 650, which may be a testing device executing testing software that supports hardware-in-loop (HILS), software-in-loop (SILS), simulated electronic control units (ECUs) connected via a virtual wire harness, and so on. Thus, the cloud service 645 can provide access to the DUTs 530-545 and 625-635 and/or virtual/emulated wire harnesses, including the DUTs 530-545 and 625-635. As such, the test entity 650, in one or more approaches, uses the cloud service 645 to form more complex virtual wire harnesses that can include emulated entities (e.g., ECUs) and can also provide access for various software routines. In this way, the cloud service 645 provides interface bridging that enables complex test bench setups and multiple interconnected ECUs to be dynamically provisioned without physical vehicle wire harnesses. Thus, instead of implementing a single large test bench with many ECUs connected via physical wiring, each separate ECU can be installed as a DUT in a server rack associated with an interface device and can be dynamically connected via an emulated wire harness to other ECUs, thereby providing for rapid testing across many different wire harnesses or vehicle variants.

Moreover, the cloud service 645 accepts and manages reservations for a set of DUTs (e.g., ECUs). In general, the cloud service 645 queues requests for jobs (e.g., testing) such that usage of the separate DUTs at the different edge networks managed by the cloud service 645 is maximized. Once a reservation is granted, the cloud service 645 manages access for a requesting party to one or more edge services so that the requesting party can connect with interfaces and route traffic to and from the interfaces. The cloud service 645 may implement this service in different forms. For example, in a first approach, the cloud service 645 arranges for an associated edge service to bridge all traffic between the requesting party and the DUT (e.g., ECU) via a GRPC or other remote session protocol. The edge service is then enabled to fully control the connection to prevent malicious actors from accessing the ECU without a reservation. In a separate approach, the cloud service 645 manages the edge service to provide routing services (e.g., as an IP address and port), then the requesting party can directly connect to the ECU with the IP address and port information.

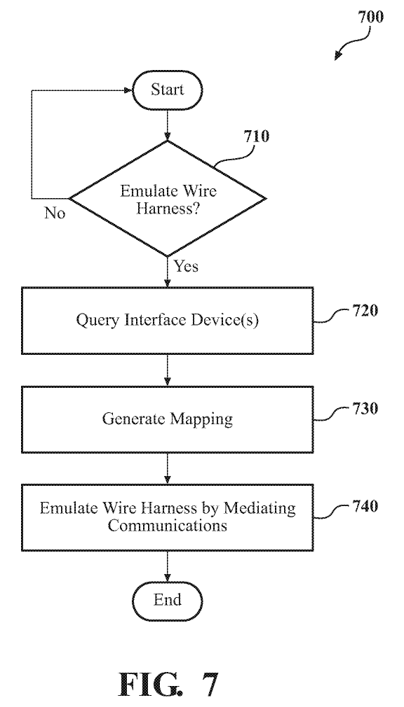

Additional aspects of using an interface device within a cloud services context will be discussed in relation to FIG. 7. FIG. 7 illustrates a flowchart of a method 400 that is associated with emulating a wire harness. Method 700 will be discussed from the perspective of the interface system 100 of FIG. 1 with further reference to the cloud service 645 of FIG. 6. While method 700 is discussed in combination with the noted elements, it should be appreciated that the method 700 is not limited to being implemented within the interface system 100 but is instead one example of a system that may implement the method 700.

At 710, the control module 120 monitors for requests from a device. The device may be the test entity 650, the test service 550, or another computing entity (e.g., a test server) that is attempting to access one or more DUTs. In particular, the request, in at least one arrangement, is in regards to emulating a wire harness. As described herein, emulating a wire harness or, stated otherwise, provisioning a virtual wire harness involves mapping available DUTs connected via interface devices to a network and routing communications therebetween according to virtual associations defined by the emulated wire harness.

Accordingly, the request may indicate a form of the wire harness and different DUTs that are to be connected. As such, the control module 120, which may execute as a client instance as part of the cloud service 645, monitors for the requests via a communication link. Once received, the control module 120 proceeds to perform additional functions in support of emulating the wire harness. Otherwise, the control module 120 proceeds with monitoring at 710.

At 720, the control module 120 queries the interface device(s). In at least one approach, the control module 120 provides queries to each separate interface device to retrieve configuration information for the multiple test devices (i.e., DUTs) that are to be virtually connected via the wire harness. In a further arrangement, the control module 120 instead queries edge services (e.g., 505, 605), which can store aggregated information from the interface devices about available DUTs. In any case, the control module 120 queries the respective entities and aggregates the configuration information in response. As previously noted, the configuration information includes information about the respective DUT (e.g., part number, serial number, etc.) and further includes information about the ports of the bridge to which the pins of the DUT are connected, which provides for facilitating communication with the DUT.

At 730, the control module 120 generates a harness mapping that identifies connections through respective interface devices. In particular, the control module 120 uses the configuration information acquired from the interface devices to define correlations between the DUTs via the port-to-pin correlations. That is, the control module 120, in one arrangement, generates a table, such as a routing table, that indicates which pins should provide signals to other specific pins of different DUTs as would be connected with a physical wire if the harness was physically connected. However, because the harness is being emulated and is virtual, the connections are represented through the harness mapping, which may take the form of a routing table. In this way, the control module 120 is able to emulate any arrangement of devices by simply providing a specific routing configuration between the pins of the devices under test.

At 740, the control module 120 emulates the wire harness. As previously described, the emulation may be performed at the cloud service 645 or the edge service (e.g., 505 or 605). In general, the service that provides the emulation simply permits a different scope of interaction with different interface devices. In particular, the cloud service 645 permits access across multiple edge networks while the edge service is limited to the interface devices connected within the particular network. In any case, the control module 120 can have separate instances executing within the different services to provide for the emulation functionality. Thus, the control module 120 uses the harness mapping to mediate communications between the separate DUTs that are included within a virtual wire harness. In one or more approaches, mediating the communications includes the control module 120 routing signals between the DUTs according to the harness mapping. Thus, the control module 120 identifies the source of the communication (i.e., a particular signal from a particular DUT) and routes the signal to one or more other DUTs according to the harness mapping. In this way, the interface system 100 is able to emulate a wire harness and provide an adaptable test bench environment that overcomes the limitations of physical arrangements.

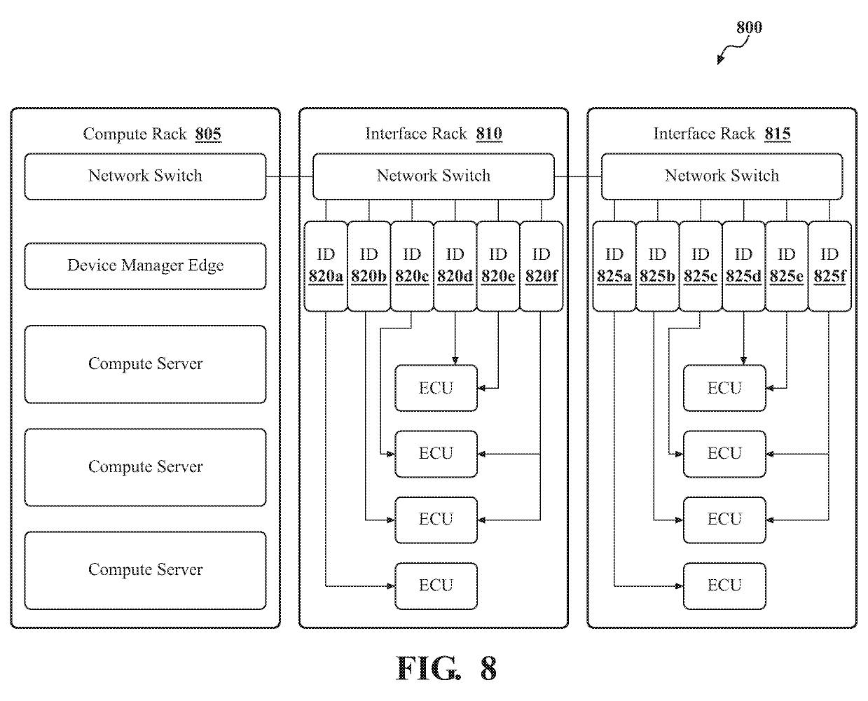

With reference to FIG. 8, one example of a rack system 800 is illustrated as it may be installed within a server. In particular, the rack system 800 is comprised of three primary elements, including a compute rack 805, an interface rack 810, and an interface rack 815. The compute rack 805 includes a network switch to connect with a network to which the other racks 810 are also connected. The compute rack 805 further includes multiple compute servers and a device manager edge. The compute servers may execute various instances of the interface system 100 and/or different test services (e.g., test service 215, test service 550, test entity 650). Thus, the automated test programs and other software that may interact with the interfaces can be executed on the compute rack 805. The interface racks 810 and 815 have similar configurations that include network switches to connect with the network and communicate with the compute rack 805. To the network switches, the interface racks 810 connect multiple interface devices, which are labeled ID 820a-f and 825a-f, to associated ECUs that are devices under test. As such, the rack system 800 provides for implementing a complex virtual wire harness via edge and cloud services executing on the compute rack 805. In this way, the adaptable interfaces (e.g., 820a-f, 825a-f) improve the testing process by avoiding complexities associated with physical harnesses.

As described above, given the general complexity of the arrangement of test devices and interface devices, configuring and setting up a test system may be complex, inefficient, and costly. Moreover, incorrect configuration of the test system components (e.g., the test devices, interface devices, and wire harnesses) can lead to erroneous test results and/or a non-functioning test system. Accordingly, the present specification describes a test template system that automatically configures the test system hardware components to ensure proper configuration and initialization of the test system components.

Specifically, the present specification describes a test hardware template that, when accounting for a specific arrangement of interface devices and DUTs (i.e., an electronic device, which is also referred to as a test device herein), defines the arrangement of hardware components, configurations of the hardware components, arrangement of wires, the purpose of the wiring, and other characteristics of the test system setup. The system can provide this hardware template to a computing device 210 to facilitate mediating communication with the test device. In one particular example, the system generates a visual representation of the hardware template, which may indicate how the hardware components should be connected for each of the interface device/test device pairs. The template may also define and automatically set up other configuration parameters associated with, for example, other emulated test devices and/or the interface devices 200. As one example, an engineer may receive the hardware template, which is loaded onto a computing device 210. The computing device 210 may then display a user interface (UI) showing the configuration and physical arrangement of the hardware components to implement the test system (i.e., test devices, wires, and interface devices, etc.). The UI may also generate a wiring diagram for the test system. Once set up, the computing device 210 may utilize the hardware template to perform health checks and validate all connections. That is, the hardware template can then cause the system to automatically test each connection to verify the correct setup. In this way, the hardware template ensures a correct arrangement of the complex test system.

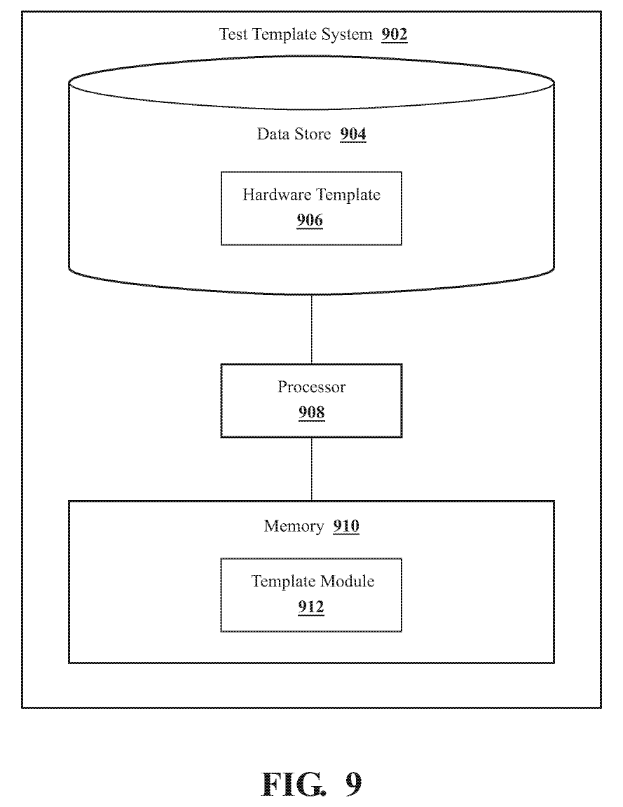

FIG. 9 illustrates one embodiment of a test template system 902 that is associated with setting up a templatized test system. The test template system 902 is shown as including a processor 908, which may be integrated within the test template system 902 or may be associated with a separate computing device, such as a server, cloud-computing system, and so on. Accordingly, the processor 908 may be a part of the test template system 902, or the test template system 902 may access the processor 908 through a data bus or another communication path. In one embodiment, the test template system 902 includes a memory 910 that stores a template module 912. The memory 910 is a random-access memory (RAM), read-only memory (ROM), a hard-disk drive, a flash memory, or another suitable memory for storing the template module 912. The template module 912 is, for example, computer-readable instructions that, when executed by the processor 908, cause the processor 908 to perform the various functions disclosed herein. In alternative arrangements, the template module 912 is independent from the memory 910 and is, for example, comprised of hardware elements (e.g., arrangements of logic gates). Thus, the template module 912 is alternatively an ASIC, a hardware-based controller, a composition of logic gates, or another hardware-based solution.

The test template system 902, as illustrated in FIG. 9, is an abstracted form of the test template system 902 as may be implemented as part of an edge service and/or a cloud-computing system. It should be appreciated that the functionality discussed in relation to the test template system 902 may be wholly retained within a single device, such as the interface device itself, or may be distributed among multiple different devices, such as interface devices, computing elements functioning as edge services, computing elements functioning as cloud services, and so on. As such, the particular arrangement described in relation to FIG. 9 is not intended to be limiting but as an example of how the specific functions described herein may be executed in relation to a computing device.

The data store 904 may house the hardware template 906 as described herein. That is, as described below in greater detail, the hardware template 906 may include information such as a test device definition, a port-to-port mapping between a test device (e.g., a DUT 205) port and an interface device 200 port, or a wiring harness diagram. In this example, the data store 904 logs this hardware template 906, such that the hardware template 906 may be called to configure and set up the test system (e.g., the interface device 200, test device, and wiring therebetween).

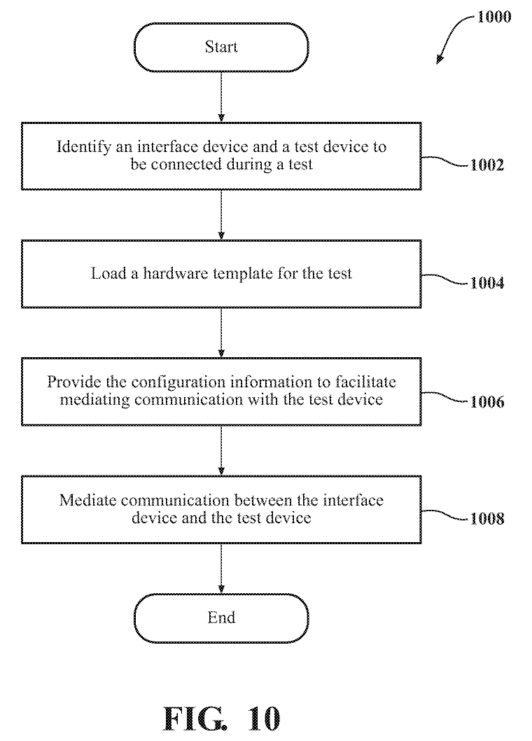

FIG. 10 illustrates a flowchart for one embodiment of a method 1000 that is associated with setting up a templatized test system. At 1002, the machine-readable instructions of the template module 912 cause the processor 908 to identify an interface device 200 and a test device (e.g., an electronic device or DUT 205) to be connected during a test. That is, in general, the test relies on multiple connected devices, such as interface devices 200 and test devices, to emulate a larger system, such as a vehicle system. Accordingly, the test template system 902 may determine which interface devices 200 and test devices are connected during a test. The identification of devices to be connected may take different forms. In one example, they may be selected based on selected test devices and interface devices 200. For example, an engineer may, via a web portal or other user interface, select the test devices and interface devices to be used during the test.

In another example, the identification may be based on a selected vehicle system to be tested. That is, vehicle systems may be divided into systems, with different systems having a domain or particular functional area. Example domains include a powertrain domain, an infotainment domain, and an advanced driver assistance system (ADAS) domain. A domain-based test may call for multiple interface devices 200 and multiple test devices to replicate the domain. Accordingly, in this example, the hardware template 906 that is ultimately loaded may reflect the configuration information for each of the test devices that pertain to a selected vehicle system (e.g., domain) and each of the interface devices used during the test.

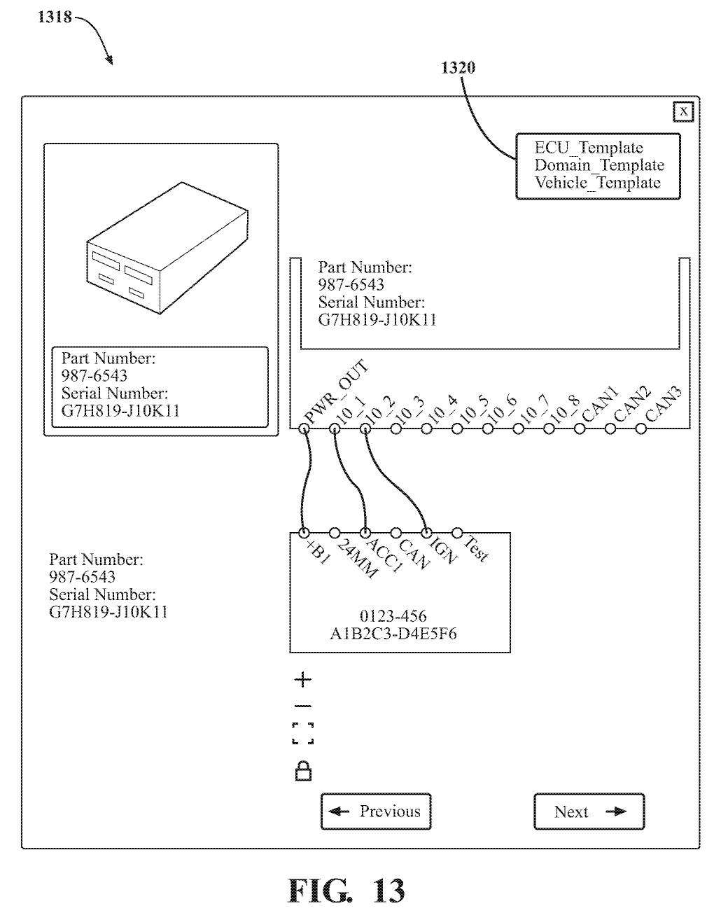

As yet another example, the identification of test devices and interface devices 200 may be based on a selected vehicle. As an extension of the previous example, an engineer may select, via the web portal or other interface, an entire vehicle to replicate. In this example, the hardware template 906 may provide configuration information for each of the different domains and their respective test devices and interface devices. In any case, identification of the interface device and test devices prescribes the hardware template 906 that is retrieved. FIG. 13 below depicts an example of an interface wherein the interface device(s) 200 and test device(s) may be identified via any of these identified modalities. Note that while particular reference is made to particular modalities to receive an identification of test devices and interface devices of a test, such information may be identified in other ways as well.

At 1004, the machine-readable instructions of the template module 912 may cause the processor 908 to load, based on the identified interface device and the test device, a hardware template 906 for the test. Specifically, the template may be loaded from the data store 904 into an interface, where its contents can be reviewed and loaded into the corresponding hardware components for execution.

In general, the hardware template 906 indicates a test device definition that includes configuration information for port(s) of the test device. In general, the configuration information may include at least the information that enables a computing device 210 to communicate with the test device over the network. That is, the test device, to properly emulate an electronic device, may have certain protocols, parameters, and settings by which it receives and transmits information. The configuration information for the ports of the test device may define those parameters.

In general, the contents of the configuration information may vary by implementation but generally include descriptive data identifying the test device (e.g., serial number or other identifier, version number, etc.). Specific examples of configuration information that may be included in the test device definition and used to configure the test device and set its operating and/or communication parameters will now be provided.

As an example, the test device definition may indicate, for each port of the test device, a port type. Examples of port types include, but are not limited to, general-purpose input/output (GPIO) type ports, controller area network (CAN) type ports, and CAN flexible data-rate (CAN FD) type ports, among others. As another example, the test device definition may indicate a port name, which port name may be relied on to determine a mapping between ports of the test device and ports of an associated interface device 200. As another example, the test device definition may indicate a port initial state, which identifies a default condition or configuration of the port. Example initial states include, but are not limited to, input, output low, output high, pull-up or pull-down enabled, etc. As another example, the test device definition may indicate a port active level, which defines a voltage value on the port that represents an active condition. For example, the active level of a port may be 12 volts (12 V), indicating that the port is active when a signal greater than 12 V is transmitted across the port. As yet another example, the test device definition may indicate, per port, a port pin drive, which indicates an electrical driving capability of the port. Example pin drive values may be push-pull and open-drain, among others. Yet another example is the port communication direction, specifically whether the port supports input, output, or bi-directional communication with any connected interface device 200.

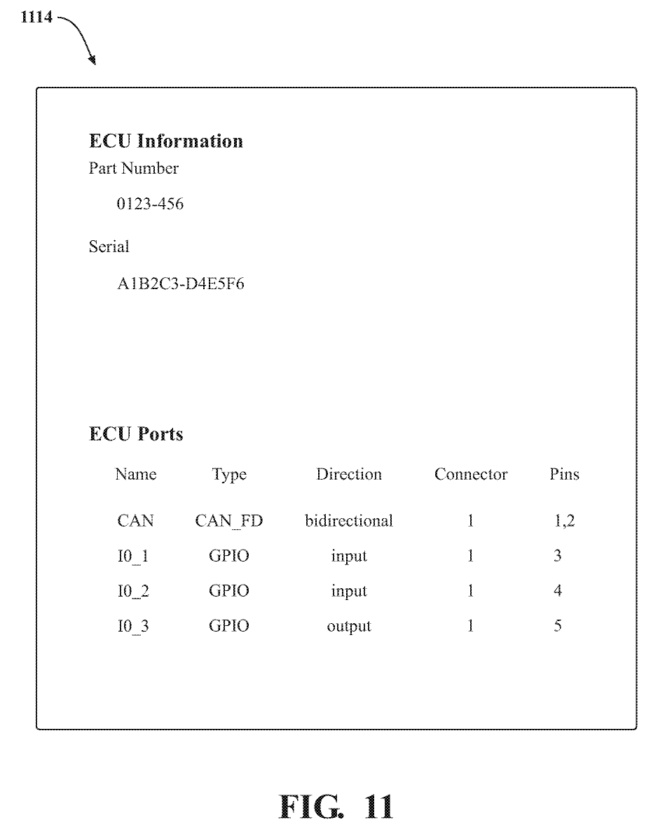

That is to say, the test device definition file may at least indicate the port properties such that a connected interface device 200 may be configured to enable communication between the computing device 210 and/or test device 215 and the test device. FIG. 11 below illustrates various examples of presenting configuration information for the ports of a particular test device. In any case, the template module 912 may define these values, generate the associated logic, and load the logic into the respective test device for execution.

In an example, the hardware template 906 may further include a mapping between test device ports to ports on an interface device 200. A computing device 210 can then form a virtual wire harness through the use of the mapping to emulate connections between the different test system hardware components (e.g., test devices and interface devices 200). That is, the computing device 210 can provide for connecting the different test devices via the interface devices in a manner similar to that of a physical wire harness, but without the complexity and waste associated with implementing a wire harness.

This mapping may facilitate the configuration of the ports of the interface device 200. That is, as described above, the different ports of the test device may expect data transmissions in certain formats. The port-to-port mapping may facilitate the initialization and alteration of the interface device 200 ports to comply with the transmission parameters of the test device. For example, suppose the mapping indicates that an accessory port (ACC) of the test device is connected to a first input/output port (IO1) on the interface device 200. In that case, the test template system 902 may initialize the IO1 port based on the configuration information for the ACC port as described in the test device definition file. FIG. 13 below depicts a port-to-port mapping as described herein.

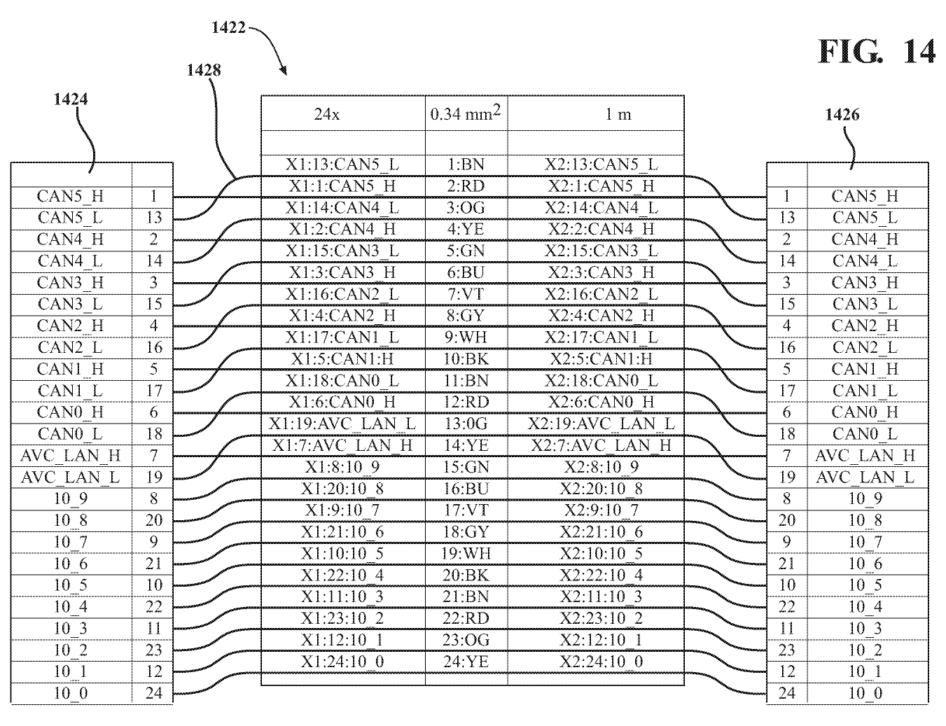

As described above, the hardware template 906 may further include a pin assignment for the port, which indicates a mapping between a logical port and a physical pin. This pin-to-port mapping permits the computing device 210 to communicate with the test device over the network connection. The mapping then facilitates communication with the test device. The pin-to-port mapping further facilitates the generation of a wiring diagram, its presentation as a visual representation, and the automatic procurement of a wire harness defined by the wiring diagram. FIG. 14 below depicts an example of the wiring diagram.

At 1006, the machine-readable instructions of the template module 912 may cause the processor 908 to provide the configuration information to facilitate mediating communication with the test device. That is, the template module 912 communicates the retrieved configuration information to the computing device 210, which is executing the test.

At 1008, the control module 120 mediates access to the test device(s). That is, for example, the control module 120 via the management controller 230 functions to control how the communications are routed to the test device(s). In various arrangements, the control module 120 simply leverages the generated mapping to provide communications to a particular test device. However, in further arrangements, the control module 120 functions to emulate a wire harness. That is, when multiple separate test devices are connected with the interface device 200 or with multiple interface devices, as discussed further subsequently, the control module 120 can emulate a wire harness by directing the communications as though the test devices are wired in the same manner as if a physical wire harness between the test devices were present.

For example, signals generated by one test device (i.e., DUT 205) can be routed to another test device as though the devices are connected via a physical wire harness. However, the control module 120 instead functions to receive and relay the communications. This permits the control module 120 to emulate any configuration of test devices while further collecting diagnostic/analytics data about how the test devices are functioning. Moreover, the control module 120 can further extend an emulated wire harness among multiple interface devices in order to permit more complex arrangements.

FIG. 11 illustrates a test device definition 1114, according to an example described herein. As described above, the configuration information includes information about the ports of the test device that is to be connected to an interface device 200 during a test. As depicted in FIG. 11, the test device definition 1114 may include a part number, a serial number, as well as other configuration information that facilitates communication between the test device and an associated interface device 200. For example, the configuration information may include a port name, a port type, and a direction of data transmission. This information may facilitate the mapping between ports of the test device and ports of the interface device. This information may also trigger the configuration of the interface device to mediate communication between the test device and the interface device 200. For example, knowing the type and direction of data transmission, an interface device port mapped to the “CAN” port of this particular test device can be configured to receive and transmit data packets in the CAN format. This configuration also prevents the connection of dissimilar or incompatible ports. For example, knowing that the first port is a CAN_FD port, an engineer may avoid connecting this port of the test device to a dissimilar or incompatible port on the interface device 200.

In some examples, the test definition portion of the hardware template 906 may indicate a connector and pin assignment for each port. As described above, this information may be relied on in generating a wiring diagram. That is, the configuration information for an interface device 200 may include a port-to-pin mapping. Accordingly, via the port-to-pin mapping of the interface device 200 and the port-to-pin mapping of the test device, the hardware template 906 may generate a pin-to-pin mapping between the interface device 200 and the test device, which may lead to a wiring diagram and provision of an associated wire harness. As described above, the template module 912 may use this information to configure and set the operating and communication parameters for the test device. Specifically, the template module 912 may generate the associated logic and load the logic onto the test device for execution.

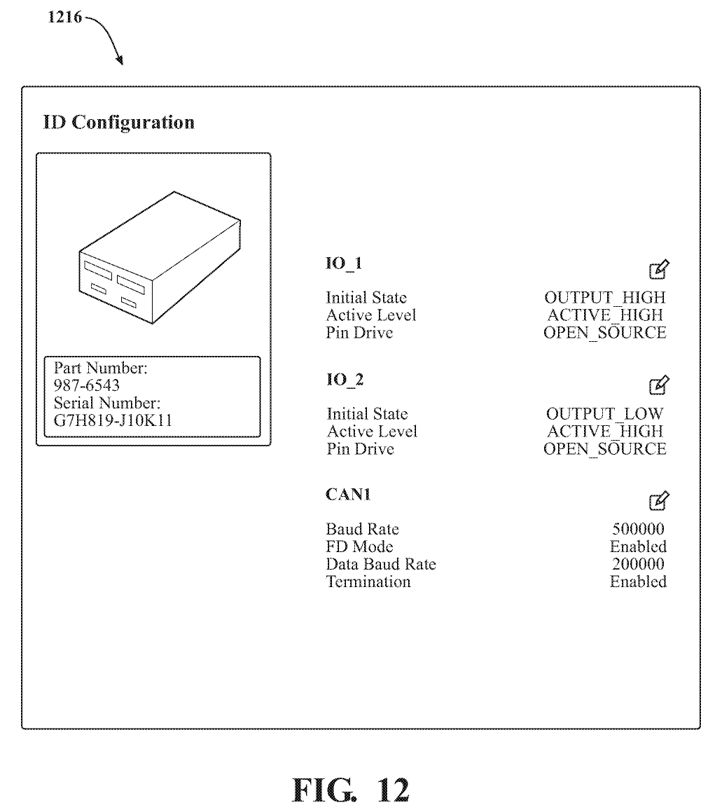

FIG. 12 illustrates an interface device definition 1216, according to an example described herein. As described above, an interface device 200 may be configurable to communicate with different test devices. When communicating with different test devices, the interface device 200 may be configured differently. In this example, the hardware template 906 indicates configuration parameters for the interface device 200 connected to the test device. That is, in this example, in addition to including test device configuration information, the hardware template 906 may include and implement configuration parameters at the interface device 200. Accordingly, in this example, the machine-readable instructions of the template module 912 may provide the configuration parameters for the interface device to facilitate mediating a connection with the test device.

Specifically, the template module 912 may provide the configuration parameters to the computing device 210 for communicating with the test device over the network connection. The contents of the configuration information may vary by implementation, but generally include descriptive data that identifies the interface device (e.g., serial number, part number, or other unique identifier). Other examples of configuration information for the ports of the interface device 200 include a port name (e.g., IO_1, IO_2, CAN1), which port name may be relied on when generating the mapping between the ports of the interface device 200 and an associated test device. As another example, the configuration may indicate a port initial state, which identifies a default condition or configuration of the port. Example initial states include, but are not limited to, input, output low, output high, pull-up or pull-down enabled, etc. As another example, the interface device definition 1216 may indicate a port active level, which indicates whether the port performs its intended action when a voltage value is high (e.g., ACTIVE_HIGH) or when the voltage value is low (e.g., ACTIVE_LOW). As yet another example, the test device definition may indicate, per port, a port pin drive, which indicates an electrical driving capability of the port. Example pin drive values include push-pull, open-drain, open-source, and high-Z, among others. Other examples of interface device port configuration parameters include the baud rate, data baud rate, configuration type, whether specific modes (e.g., an FD mode for a CAN port) are available, and whether bus termination is enabled. Note that while particular reference is made to particular configuration parameters for the interface device, the hardware template 906 may include other configuration parameters. Note that these configuration parameters may be defined based on the configuration information from the test device definition. That is, a user may select (as depicted in FIG. 13) a particular test device, after which the test template system 902 may generate the mapping and configuration information for the interface device. The mapping may be presented on a user interface and the configuration information may be provided to the computing device 210 to facilitate communication between the interface device and the test device. That is, as described above, the template module 912 may use this information to configure and set the operating and communicating parameters for the interface device 200. Specifically, the template module 912 may generate the associated logic and load the logic onto the interface device 200 for execution.

FIG. 13 illustrates one example of a port-to-port mapping 1318, according to an example described herein. As described above, in an example, the hardware template 906 indicates a mapping between ports of the test device and ports of an associated interface device 200 based on the tested device definition. The mapping indicates which ports of an interface device 200 should provide signals to ports of the different test devices, as would be connected with a physical wire if the harness were physically connected. In doing so, the test template system 902 builds a mapping that enables routing signals generated by the test service 215 when executing a test program to the appropriate port of the test devices. In general, the mapping defines ports of the interface device 200 for communicating signals on particular ports of the test device(s). In this way, the interface device 200 exposes the test devices for interactions with external devices.

Specifically, the test template system 902 generates the mapping so that the computing device 210 can translate test instructions from the test service 215 and communicate the test instructions on the appropriate ports of the interface device 200. Thus, the computing device 210 uses the port-to-port mapping to mediate communications between the separate test devices included within the test system. In one or more approaches, mediating the communications includes the computing device 210 routing signals between the test devices according to the port-to-port mapping. Thus, the computing device 210 identifies the source of the communication (i.e., a particular signal from a specific test device) and routes the signal to one or more other test devices according to the port-to-port mapping. In this way, the computing device 210 is able to emulate a wire harness and provide an adaptable test bench environment that overcomes the limitations of physical arrangements.

In an example, the computing device 210 could then form a virtual wire harness through the use of the mapping to emulate connections between the different test system components (e.g., test devices and interface devices 200). In this way, the template module 912 is able to emulate any arrangement of devices by simply providing a specific routing configuration between the ports of the test devices and interface devices 200.

For example, the instructions of the template module 912 may cause the processor 908 to display a visual representation of the mapping on the user interface. FIG. 13 depicts such a visual representation. Note that while FIG. 13 depicts the mapping as a diagrammatic representation, the visual representation may be implemented in other forms, such as a list, a table, or another data structure that correlates the ports of the test device to ports of the interface device.

FIG. 13 also depicts a drop-down menu 1320 from which a user may identify interface devices 200 and test devices. As described above, a user may select the test devices at different hierarchical levels, for example, as individual devices, as part of a domain/system, or as part of a vehicle. In any case, based on a selection, the hardware template 906, along with any information it contains (test device definitions, interface device configuration parameters, port-to-port mappings, and wiring diagrams), may be provided to facilitate communication within the test system and/or presented as a visual representation.

FIG. 14 illustrates one example of a wiring diagram 1422 between a test device connector 1424 and an interface device connector 1426, according to an example described herein. As described above, the hardware template 906 may indicate pin assignments, specifically which pins of a test device connector 1424 correspond to ports of a test device. Based on the pin-to-port assignments and the port-to-port mapping depicted in FIG. 13, the machine-readable instructions of the template module 912 may cause the processor 908 to present a wiring diagram 1422 between the test device connector 1424 and an associated interface device connector 1426. That is, from this wiring diagram 1422, an engineer could physically construct the wire harness for the test system.

As indicated in FIG. 14, the wiring diagram 1422 may indicate physical characteristics of the various wires (one of which is indicated with a reference number) and connectors. For example, the wiring diagram 1422 may indicate the different pins on either connector as well as the pin names. The wiring diagram 1428 may also indicate the physical characteristics of the wire, such as the gauge and length of the wire.

In some examples, in addition to generating the wiring diagram 1422, the test template system 902 may automatically identify (for example, via part number), reserve, purchase, or otherwise acquire the wire harness defined by the wiring diagram 1422. That is to say, the wiring diagram 1422 may correspond with a physical wire harness with a unique identifier. The template module 912 may, in some examples, identify the unique identifier of the physical wire harness that is represented by the wiring diagram 1422 and provide the identifier to the engineer. In another example, the template module 912 may reserve the wire harness from a pool of resources.

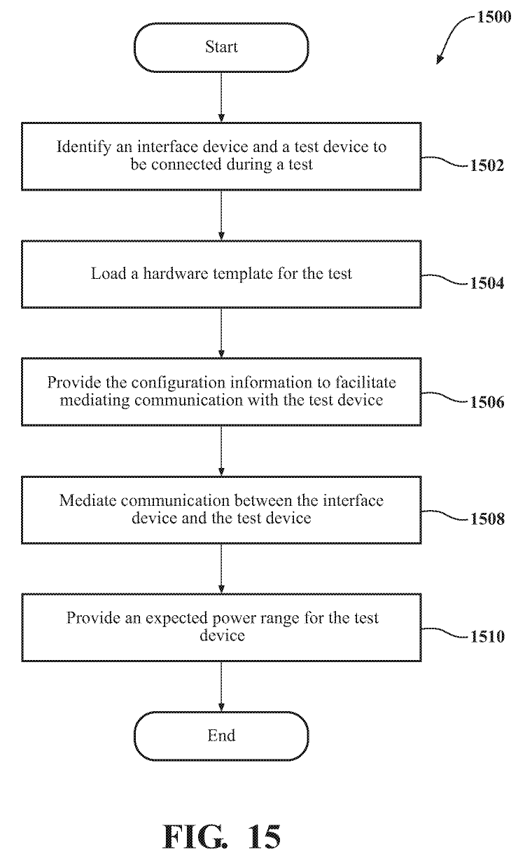

FIG. 15 illustrates a flowchart for one embodiment of a method 1500 that is associated with setting up a templatized test system. Some of the operations described herein may be implemented as described above. Specifically, at 1502, the template module 912 may identify an interface device 200 and a test device to be connected during a test, and at 1504, the template module 912 may load a hardware template for the test. At 1506, the template module 912 may provide the configuration information to facilitate mediating communication with the test device, and at 1508, mediate communication between the interface device 200 and the test device.

In some examples, additional operations may be performed. For example, the hardware template 906 may further define an expected power range for the tested device. That is, during the regular operation of the test device, different voltage values may be expected on different pins. In this example, the template module 912, at 1510, may provide the expected power range for the test device, for example, to the computing device 210. This allows the computing device 210 to validate the connection between the test device and the interface device 200 during the test's execution. That is, if a measured voltage is a threshold amount different than the expected value, it may indicate that there is something wrong with the connection. At this point, the computing device 210 may take various remedial actions, such as generating a notification or preventing the test from being executed. In this example, the template module 912 may generate the logic associated with the validation check and load the logic onto the interface device 200 and/or the test device.

Accordingly, the present test template system 902, based on identified interface devices 200 and test devices to be used during a test, automatically acquires the configuration information for both the test devices and the interface devices 200 via the hardware template 906. In some cases, the hardware template 906 may further define the mappings between the ports on respective devices based on the templatized configuration information. If the configuration information for the test device includes pin assignments for the various test device ports, the hardware template 906 may also include a wiring diagram, which indicates the arrangement of different physical cables between the test device connector 1424 and the interface device connector 1426.

Detailed embodiments are disclosed herein. However, it is to be understood that the disclosed embodiments are intended only as examples. Therefore, specific structural and functional details disclosed herein are not to be interpreted as limiting but merely as a basis for the claims and as a representative basis for teaching one skilled in the art to variously employ the aspects herein in virtually any appropriately detailed structure. Further, the terms and phrases used herein are not intended to be limiting but rather to provide an understandable description of possible implementations. Various embodiments are shown in FIGS. 1-8, but the embodiments are not limited to the illustrated structure or application.

The flowcharts and block diagrams in the figures illustrate the architecture, functionality, and operation of possible implementations of systems, methods, and computer program products according to various embodiments. In this regard, each block in the flowcharts or block diagrams may represent a module, segment, or portion of code, which comprises one or more executable instructions for implementing the specified logical function(s). It should also be noted that, in some alternative implementations, the functions noted in the block may occur out of the order noted in the figures. For example, two blocks shown in succession may, in fact, be executed substantially concurrently, or the blocks may sometimes be executed in the reverse order, depending upon the functionality involved.

The systems, components and/or processes described above can be realized in hardware or a combination of hardware and software and can be realized in a centralized fashion in one processing system or in a distributed fashion where different elements are spread across several interconnected processing systems. The systems, components and/or processes also can be embedded in a computer-readable storage, such as a computer program product or other data program storage device, readable by a machine, tangibly embodying a program of instructions executable by the machine to perform methods and processes described herein. These elements also can be embedded in an application product which comprises the features enabling the implementation of the methods described herein and, which when loaded in a processing system, is able to carry out these methods.

Furthermore, arrangements described herein may take the form of a computer program product embodied in one or more computer-readable media having computer-readable program code embodied, e.g., stored, thereon. The phrase “computer-readable storage medium” means a non-transitory storage medium. A computer-readable storage medium may be, for example, an electronic, magnetic, optical, electromagnetic, infrared, or semiconductor system, apparatus, or device, or any suitable combination of the foregoing. A non-exhaustive list of the computer-readable storage medium can include the following: a portable computer diskette, a hard disk drive (HDD), a solid-state drive (SSD), a read-only memory (ROM), an erasable programmable read-only memory (EPROM or Flash memory), a portable compact disc read-only memory (CD-ROM), a digital versatile disc (DVD), an optical storage device, a magnetic storage device, or a combination of the foregoing. In the context of this document, a computer-readable storage medium is, for example, a tangible medium that stores a program for use by or in connection with an instruction execution system or device.

Computer program code for carrying out operations for aspects of the present arrangements may be written in any combination of one or more programming languages, including an object-oriented programming language such as Java™, Smalltalk, C++ or the like and conventional procedural programming languages, such as the “C” programming language or similar programming languages. The program code may execute entirely on the user's computer, partly on the user's computer, as a stand-alone software package, partly on the user's computer and partly on a remote computer, or entirely on the remote computer or server. In the latter scenario, the remote computer may be connected to the user's computer through a network, including a local area network (LAN) or a wide area network (WAN), or the connection may be made to an external computer (for example, through the Internet using an Internet Service Provider).

The terms “a” and “an,” as used herein, are defined as one or more than one. The term “plurality,” as used herein, is defined as two or more than two. The term “another,” as used herein, is defined as at least a second or more. The terms “including” and/or “having,” as used herein, are defined as comprising (i.e., open language). The phrase “at least one of … and ….” as used herein refers to and encompasses any and all possible combinations of one or more of the associated listed items. As an example, the phrase “at least one of A, B, and C” includes A only, B only, C only, or any combination thereof (e.g., AB, AC, BC or ABC).

Aspects herein can be embodied in other forms without departing from the spirit or essential attributes thereof. Accordingly, reference should be made to the following claims, rather than to the foregoing specification, as indicating the scope hereof.

What is claimed is:

1. A system, comprising:
a processor; and
a memory storing machine-readable instructions that, when executed by the processor, cause the processor to:
identify an interface device and a test device to be connected during a test;
load, based on the interface device and the test device, a hardware template for the test from memory, the hardware template indicates a test device definition that includes configuration information for a port of the test device; and
provide the configuration information to facilitate mediating communication with the test device.

2. The system of claim 1, wherein the test device definition indicates, for different ports of the test device, at least one of:
a port type;
a port name; or
a port communication direction.

3. The system of claim 1, wherein:
the hardware template further indicates a mapping between ports of the test device and ports of an associated interface device based on the test device definition; and
the memory further stores a machine-readable instruction that, when executed by the processor, causes the processor to present a visual representation of the mapping on a user interface.

4. The system of claim 3, wherein:
the hardware template further indicates a pin assignment for a test device connector based on the mapping; and
the memory further stores a machine-readable instruction that, when executed by the processor, causes the processor to present a wiring diagram from the test device connector to a connector of an associated interface device, the wiring diagram indicates physical characteristics of wires and connectors.

5. The system of claim 4, wherein the memory further stores a machine-readable instruction that, when executed by the processor, causes the processor to provision a wiring harness between the test device and the associated interface device that corresponds to the wiring diagram.

6. The system of claim 1, wherein:
the hardware template indicates configuration parameters for the interface device connected to the test device; and
the memory further stores a machine-readable instruction that, when executed by the processor, causes the processor to provide the configuration parameters for the interface device to facilitate mediating connection with the test device.

7. The system of claim 1, wherein the machine-readable instruction to identify the interface device and the test device comprises a machine-readable instruction that, when executed by the processor, causes the processor to identify the interface device and the test device based on at least one of:
a selected vehicle to be tested;
a selected vehicle system to be tested; or
selected test devices and interface devices.

8. The system of claim 1, wherein:
the hardware template further defines an expected power range for the test device; and
the memory further comprises a machine-readable instruction that, when executed by the processor, causes the processor to provide the configuration information to facilitate validating a connection between the test device and the interface device.

9. The system of claim 1, wherein the test device is a vehicle electronic control unit (ECU) that includes connector pins for forming a connection to an associated interface device.

10. A non-transitory machine-readable medium comprising instructions that, when executed by a processor, cause the processor to:
identify an interface device and a test device to be connected during a test;
load, based on the interface device and the test device, a hardware template for the test from memory, the hardware template indicates a test device definition that includes configuration information for a port of the test device; and
provide the configuration information to facilitate mediating communication with the test device.

11. The non-transitory machine-readable medium of claim 10, wherein the test device definition indicates, for different ports of the test device, at least one of:
a port type;
a port name; or
a port communication direction.

12. The non-transitory machine-readable medium of claim 10, wherein:
the hardware template further indicates a mapping between ports of the test device and ports of an associated interface device based on the test device definition; and
the non-transitory machine-readable medium further comprises an instruction that, when executed by the processor, causes the processor to present a visual representation of the mapping on a user interface.

13. The non-transitory machine-readable medium of claim 12, wherein:
the hardware template further indicates a pin assignment for a test device connector based on the mapping; and
the non-transitory machine-readable medium further comprises an instruction that, when executed by the processor, causes the processor to present a wiring diagram from the test device connector to a connector of an associated interface device, the wiring diagram indicates physical characteristics of wires and connectors.

14. The non-transitory machine-readable medium of claim 10, wherein the instruction to identify the interface device and the test device comprises an instruction that, when executed by the processor, causes the processor to identify the interface device and the test device based on at least one of:
a selected vehicle to be tested;
a selected vehicle system to be tested; or
selected test devices and interface devices.

15. The non-transitory machine-readable medium of claim 10, wherein:
the hardware template further defines an expected power range for the test device; and
the non-transitory machine-readable medium further comprises an instruction that, when executed by the processor, causes the processor to provide the configuration information to facilitate validating a connection between the test device and the interface device.

16. A method, comprising:
identifying an interface device and a test device to be connected during a test;
loading, based on the interface device and the test device, a hardware template for the test from memory, the hardware template indicates a test device definition that includes configuration information for a port of the test device; and
providing the configuration information to facilitate mediating communication with the test device.

17. The method of claim 16, wherein the test device definition indicates, for different ports of the test device, at least one of:
a port type;
a port name;
a port initial state;
a port active level;
a port pin drive; or
a port communication direction.

18. The method of claim 16, wherein:
wherein the hardware template further indicates a mapping between ports of the test device and ports of an associated interface device based on the test device definition; and
the method further comprises presenting a visual representation of the mapping on a user interface.

19. The method of claim 18, wherein:
wherein the hardware template further indicates a pin assignment for a test device connector based on the mapping; and
the method further comprises presenting a wiring diagram from the test device connector to a connector of an associated interface device, the wiring diagram indicates physical characteristics of wires and connectors.

20. The method of claim 16, wherein identifying the interface device and the test device comprises identifying the interface device and the test device based on at least one of:
a selected vehicle to be tested;
a selected vehicle system to be tested; or
selected test devices and interface devices.
